(19) United States
(12) Patent Application Publication
(10) Pub. No.: US 2025/0185436 A1
(43) Pub. Date: Jun. 5, 2025

(54) DISPLAY PANEL AND DISPLAY DEVICE

(71) Applicant: Wuhan Tianma Micro-Electronics Co., Ltd., Wuhan (CN)

(72) Inventors: Yu CAI, Wuhan (CN); Jiaxian LIU, Wuhan (CN)

(73) Assignee: Wuhan Tianma Micro-Electronics Co., Ltd., Wuhan (CN)

(21) Appl. No.: 18/690,799

(22) PCT Filed: Dec. 7, 2022
(86) PCT No.: PCT/CN2022/137102

§ 371 Date: Mar. 11, 2024

(30) Foreign Application Priority Data
Aug. 26, 2022 (CN) 202211034246.1

(51) Int. Cl. H10H 29/85; H01L 25/075; H10H 29/855

(52) U.S. Cl. CPC H10H 29/8517; H01L 25/0753; H10H 29/8552

(57) ABSTRACT

Provided are a display panel and a display device. The display panel includes a first display region and a second display region, where the second display region surrounds at least part of the first display region. The display panel includes a light-emitting layer and an optical filter layer, where the light-emitting layer includes multiple light-emitting units, the optical filter layer includes multiple optical filter structures, and the multiple light-emitting units are arranged corresponding to the multiple optical filter structures. The multiple optical filter structures include a first optical filter structure located in the first display region and a second optical filter structure located in the second display region, where the first optical filter structure includes a first color resist unit, and the second optical filter structure includes a second color resist unit.

This application claims priority to Chinese Patent Application No. 202211034246.1 filed with the China National Intellectual Property Administration (CNIPA) on Aug. 26, 2022, the disclosure of which is incorporated herein by reference in its entirety.

### TECHNICAL FIELD

The present application relates to the field of display technologies, for example, a display panel and a display device.

### BACKGROUND

The development of display technologies changes quickly, and the emergence of various screen technologies provides infinite possibilities for electronic terminals. Especially, the display technologies represented by the organic light-emitting diode have been applied rapidly, and various mobile terminals with selling points such as the “full screen”, “special-shaped screen”, “in-screen speaker”, and “in-display fingerprint” start to be promoted rapidly. Major mobile phone manufacturers and panel manufacturers have launched many products with the “full screen” as the selling point, but most of them still use the “notch screen”, the “waterdrop notch display”, and other similar full-screen designs. This is because it is necessary to reserve a certain region for front-facing cameras of the mobile terminals, resulting in a relatively low proportion of the display region of the display panel. To solve the problem of the low proportion of the display region, the technicians developed a technology in which a display interface is completely covered by a display screen, that is, a photosensitive element is designed under the screen. However, the light collection effect of the photosensitive element under the screen of the display panel is not good.

### SUMMARY

The present application provides a display panel and a display device.

The present application provides a display panel. The display panel includes a first display region and a second display region, where the second display region surrounds at least part of the first display region.

The display panel includes a light-emitting layer and an optical filter layer, where the light-emitting layer includes multiple light-emitting units, the optical filter layer includes multiple optical filter structures, and the multiple light-emitting units are arranged corresponding to the multiple optical filter structures.

The multiple optical filter structures include a first optical filter structure located in the first display region and a second optical filter structure located in the second display region, where the first optical filter structure includes a first color resist unit, and the second optical filter structure includes a second color resist unit.

The filtered color of the first color resist unit and the filtered color of the second color resist unit are the same.

The light transmittance of the first optical filter structure is greater than the light transmittance of the second optical filter structure.

Correspondingly, the present application further provides a display device including the preceding display panel.

### BRIEF DESCRIPTION OF DRAWINGS

To illustrate embodiments of the present application or the related art, the drawings used in the description of the embodiments or the related art are briefly described below. The drawings described below illustrate merely the embodiments of the present application, and those of ordinary skill in the art may obtain other drawings based on the drawings described below on the premise that no creative work is done.

FIG. 1 is a structural diagram of a display panel according to an embodiment of the present application;

FIG. 2 is a structural diagram of a first display region and the surroundings according to an embodiment of the present application;

FIG. 3 is a sectional diagram taken along a direction AA′ in FIG. 2;

FIG. 4 is a structural diagram of another first display region and the surroundings according to an embodiment of the present application;

FIG. 5 is a sectional diagram taken along a direction BB′ in FIG. 4;

FIG. 6 is a structural diagram of another display panel according to an embodiment of the present application;

FIG. 7 is a structural diagram of third structures according to an embodiment of the present application;

FIG. 8 is a structural diagram illustrating the distribution of third structures according to an embodiment of the present application;

FIG. 9 is a structural diagram of a first display region according to an embodiment of the present application;

FIG. 10 is a structural diagram of another first display region according to an embodiment of the present application;

FIG. 11 is a structural diagram illustrating the distribution of second structures according to an embodiment of the present application;

FIG. 12 is a structural diagram of another first display region according to an embodiment of the present application;

FIG. 13 is a structural diagram of another first display region according to an embodiment of the present application;

FIG. 14 is a structural diagram of another first display region according to an embodiment of the present application;

FIG. 15 is a structural diagram of another display panel according to an embodiment of the present application;

FIG. 16 is a structural diagram of another display panel according to an embodiment of the present application;

FIG. 17 is a structural diagram of another display panel according to an embodiment of the present application; and

FIG. 18 is a structural diagram of a display device according to an embodiment of the present application.

### DETAILED DESCRIPTION

The embodiments of the present application are described clearly and completely below in conjunction with the drawings in the embodiments of the present application. The embodiments described below are part, not all, of the embodiments of the present application. Based on the embodiments of the present application, all other embodiments obtained by those of ordinary skill in the art without creative work are within the scope of the present application.

As mentioned in the background, to solve the problem of the low proportion of a display region, the technicians developed a technology in which a display interface is completely covered by a display screen, that is, a photosensitive element is designed under the screen. However, the light collection effect of the photosensitive element under the screen of the display panel is not good.

Based on this, the embodiments of the present application provide a display panel and a display device, so as to ensure relatively high light transmittance in a first display region, thereby improving the light collection effect in the region corresponding to the first display region.

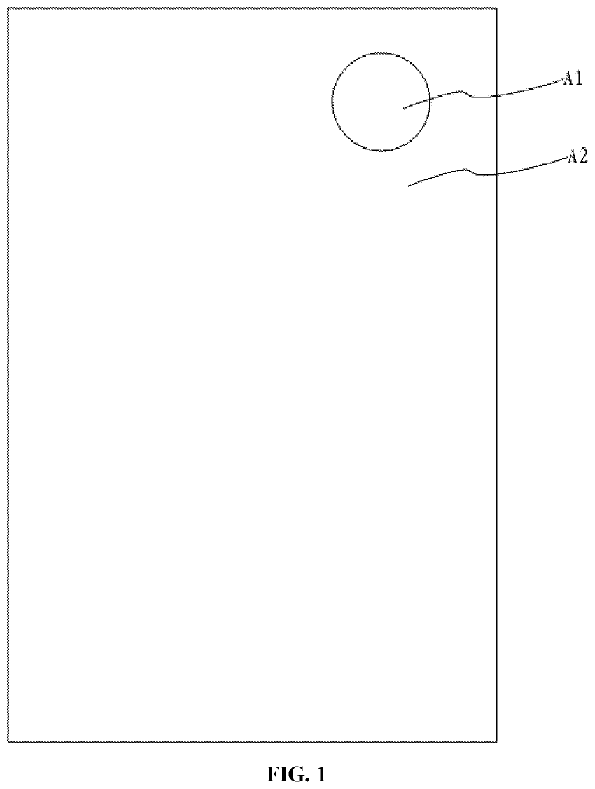

Specifically, the embodiments of the present application are described below in conjunction with FIGS. 1 to 18.

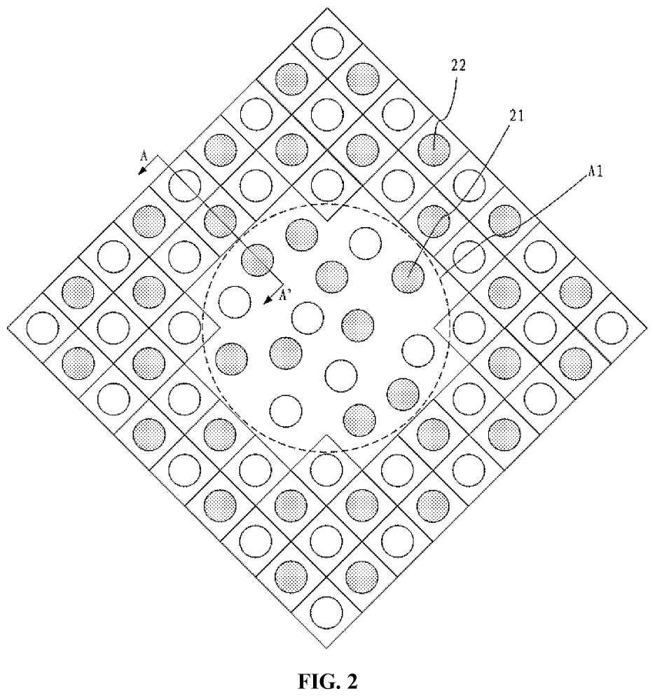

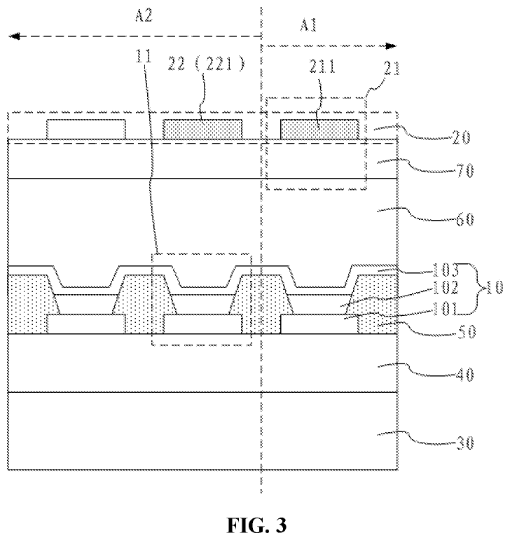

In conjunction with FIGS. 1 and 2, FIG. 1 is a structural diagram of a display panel according to an embodiment of the present application, FIG. 2 is a structural diagram of a first display region and the surroundings according to an embodiment of the present application, and FIG. 3 is a sectional diagram taken along a direction AA′ in FIG. 2. The display panel provided in the embodiment of the present application includes a first display region A1 and a second display region A2, where the second display region A2 surrounds at least part of the first display region A1.

The display panel includes a light-emitting layer 10 and an optical filter layer 20, where the light-emitting layer 10 includes multiple light-emitting units 11, the optical filter layer 20 includes multiple optical filter structures, and the multiple light-emitting units 11 are arranged corresponding to the multiple optical filter structures. The light-emitting units 11 provided in the embodiment of the present application may be in one-to-one correspondence with the optical filter structures, or in other embodiments of the present application, the multiple light-emitting units 11 correspond to one optical filter structure, which is not specifically limited in the present application.

The multiple optical filter structures include a first optical filter structure 21 located in the first display region A1 and a second optical filter structure 22 located in the second display region A2, where the first optical filter structure 21 includes a first color resist unit 211, and the second optical filter structure 22 includes a second color resist unit 221. The filtered color of the first color resist unit 211 and the filtered color of the second color resist unit 221 are the same, that is, the first color resist unit 211 and the second color resist unit 221 can allow the light of the same color to pass through and filter other colors. The light transmittance of the first optical filter structure 21 is greater than the light transmittance of the second optical filter structure 22.

It is to be understood that in the embodiment of the present application, the light transmittance of the first optical filter structure 21 is configured to be greater than the light transmittance of the second optical filter structure 22, further improving the light transmittance in the first display region A1, thereby improving the light collection effect in the region corresponding to the first display region A1.

As shown in FIG. 1, the display region of the display panel provided in the present application is divided into the first display region A1 and the second display region A2, where the first display region A1 may be completely or partially surrounded by the second display region A2.

As shown in FIG. 1, the first display region A1 may be located at a corner of the display region. In other embodiments, the first display region A1 may also be located at the midpoint of the display region, at a position to the right of the center, at a position in contact with the left or right edge of the display region, or the like, which is not specifically limited in the present application. Moreover, the first display region A1 provided in the embodiment of the present application may be a regular figure such as a circle, an ellipse, or a rectangle; alternatively, in other embodiments of the present application, the first display region A1 may also be an irregular figure, which is not specifically limited in the present application.

As shown in FIG. 3, the display panel provided in the embodiment of the present application includes a substrate 30; a transistor array layer 40 located on the substrate 30, where the transistor array layer 40 includes multiple transistors and multiple capacitors, where the transistors and the capacitors are used for forming a pixel circuit that provides the drive current for the light-emitting units 11 and forming a structure such as a driver circuit that provides a drive signal for the pixel circuit; an anode layer 101 located on the transistor array layer 40 and including multiple anode blocks; a pixel defining layer 50 located on the anode layer 101 and including multiple hollows, where the hollows correspond to the anode blocks; a light-emitting layer 102 located in the hollows of the pixel defining layer 50 and located on the anode blocks; and a cathode layer 103 located on the light-emitting layer 102, where the anode layer 101, the light-emitting layer 102, and the cathode layer 103 form the light-emitting layer 10, and the anode blocks, the light-emitting layer 102, and the cathode layer 103 form the light-emitting units 11.

In addition, the display panel further includes an encapsulation layer 60 located on the cathode layer 103; a touch layer 70 located on the encapsulation layer 60; and the optical filter layer 20 located on the touch layer 70 and including the first optical filter structure 21, the second optical filter structure 22, and other optical filter structures, where the first optical filter structure 21 includes the first color resist unit 211, the second optical filter structure 22 includes the second color resist unit 221, and other optical filter structures include color resist units with other colors.

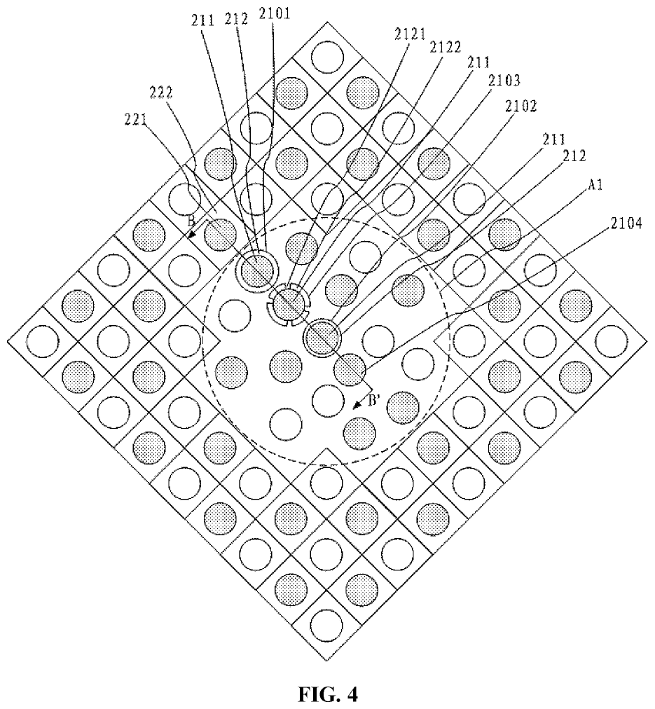

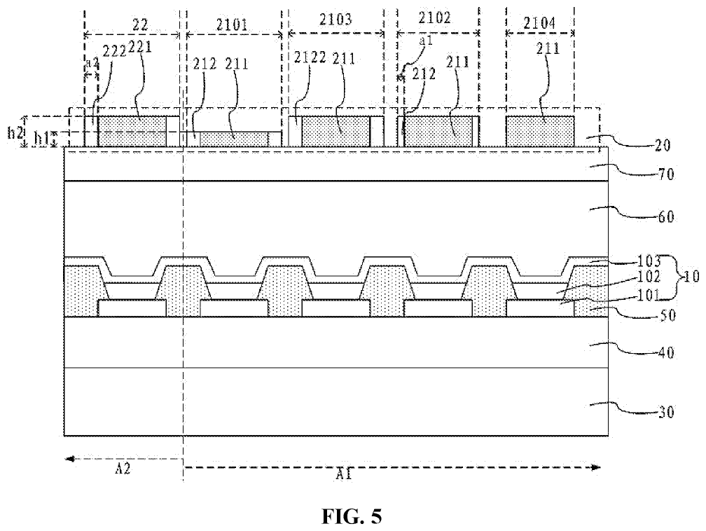

In an embodiment of the present application, the light transmittance of the first optical filter structure 21 provided in the present application is greater than the light transmittance of the second optical filter structure 22. For this, in the embodiment of the present application, the thickness of the color resist unit of the optical filter structure and other parameters are optimized and improved. In conjunction with FIGS. 4 and 5, FIG. 4 is a structural diagram of another first display region and the surroundings according to an embodiment of the present application, and FIG. 5 is a sectional diagram taken along a direction BB′ in FIG. 4. The second optical filter structure 22 provided in the embodiment of the present application further includes a second black matrix 222 surrounding the second color resist unit 221, where the second black matrix 222 acts as a light-shielding function, the second black matrix 222 includes a light-transmissive hollow, and the second color resist unit 221 fills the light-transmissive hollow. In the second display region A2, other optical filter structures also include black matrices, and the black matrices in the second display region A2 are in contact with each other to prevent the problem of light leakage in the second display region A2.

Moreover, the first optical filter structure 21 provided in the embodiment of the present application includes at least one of a first structure 2101, a second structure 2102, a third structure 2103, or a fourth structure 2104.

The first structure 2101 includes the first color resist unit 211 and a first black matrix 212 surrounding the first color resist unit 211, where the thickness h1 of the first color resist unit 211 is less than the thickness h2 of the second color resist unit 221.

The second structure 2102 includes the first color resist unit 211 and the first black matrix 212 surrounding the first color resist unit 211, where the width a1 of the first black matrix 212 is less than the width a2 of the second black matrix 222.

The third structure 2103 includes the first color resist unit 211 and the first black matrix surrounding the first color resist unit 211, where the first black matrix includes first hollows 2121 and black matrix blocks 2122, and the first hollows 2121 penetrate the first black matrix and extend to the first color resist unit 211 in the direction from the first black matrix to the center of the first color resist unit 211.

The fourth structure 2104 includes the first color resist unit 211, where the first black matrix is not disposed around the first color resist unit 211.

It is to be understood that in the display panel provided in the embodiment of the present application, the first optical filter structure 21 includes at least one of the first structure 2101, the second structure 2102, the third structure 2103, or the fourth structure 2104, that is, the first optical filter structure 21 includes the first structure 2101, and/or the second structure 2102, and/or the third structure 2103, and/or the fourth structure 2104. In the first structure 2101, the first black matrix 212 includes a light-transmissive hollow, the first color resist unit 211 fills the light-transmissive hollow, the thickness h1 of the first color resist unit 211 of the first structure 2101 is less than the thickness h2 of the second color resist unit 221, and the light transmittance of the first color resist unit 211 is increased by reducing the thickness of the first color resist unit 211, thereby improving the light emission efficiency of the light-emitting unit corresponding to the first color resist unit 211 and improving the light transmittance of the first structure 2101. For example, in the first structure 2101, the width of the first black matrix 212 may be configured to be the same as the width of the second black matrix 222, or the width of the first black matrix 212 may be configured to be less than the width of the second black matrix 222.

In the second structure 2102, the first black matrix 212 includes a light-transmissive hollow, the first color resist unit 211 fills the light-transmissive hollow, and the width of the first black matrix 212 is configured to be less than the width of the second black matrix 222, thereby relatively reducing the light-shielding area of the first black matrix 212 to the light-emitting unit and improving the light transmittance of the second structure 2102. For example, in the second structure 2102, the thickness of the first color resist unit 211 may be configured to be the same as the thickness of the second color resist unit 221, or the thickness of the first color resist unit 211 may be configured to be less than the thickness of the second color resist unit 221.

In the third structure 2103, the first black matrix includes a light-transmissive hollow, and the first color resist unit 211 fills the light-transmissive hollow; moreover, the first black matrix includes the first hollows 2121 and the black matrix blocks 2122, and the first hollows 2121 can reduce the light-shielding area of the first black matrix, thereby improving the light transmittance of the third structure 2103. For example, in the third structure 2103, the thickness of the first color resist unit 211 may be configured to be the same as the thickness of the second color resist unit 221, or the thickness of the first color resist unit 211 may be configured to be less than the thickness of the second color resist unit 221; and the width of the first black matrix may be configured to be the same as the width of the second black matrix 222, or the width of the first black matrix may be configured to be less than the width of the second black matrix 222.

Moreover, in the fourth structure 2104, the fourth structure 2104 includes only the first color resist unit 211 and does not include the first black matrix surrounding the first color resist unit 211, so the light-shielding problem of the first black matrix can be avoided, and the light transmittance of the fourth structure 2104 can be improved.

The first optical filter structure 21 provided in the embodiment of the present application includes one or more of the first structure 2101, the second structure 2102, the third structure 2103, or the fourth structure 2104, thereby improving the light transmission of the first display region A1.

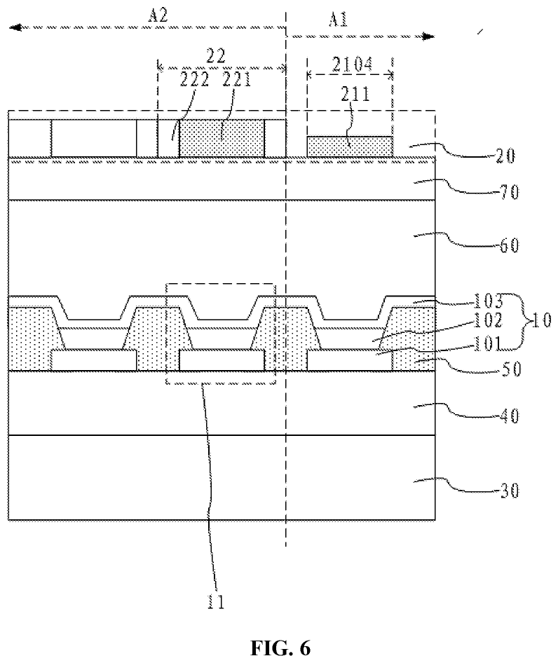

As shown in FIG. 6, FIG. 6 is a structural diagram of another display panel according to an embodiment of the present application. The first optical filter structure includes the fourth structure 2104, and in the fourth structure 2104, the thickness of the first color resist unit 211 is less than the thickness of the second color resist unit 221, thereby further improving the light transmittance of the fourth structure 2104. Alternatively, in other embodiments of the present application, the thickness of the first color resist unit 211 of the fourth structure 2104 may be configured to be equal to the thickness of the second color resist unit 221.

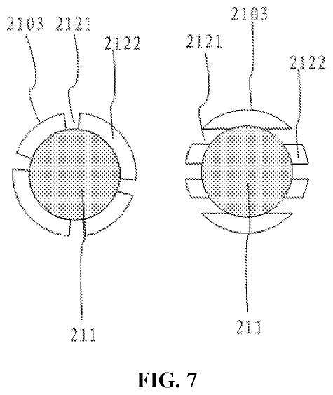

As shown in FIG. 7, FIG. 7 is a structural diagram of third structures according to an embodiment of the present application. The first optical filter structure provided in the embodiment of the present application includes the third structure 2103, the third structure 2103 includes multiple first hollows 2121 and multiple black matrix blocks 2122, and the first hollows 2121 and the black matrix blocks 2122 are arranged alternately. In the embodiment of the present application, the first hollows 2121 and the black matrix blocks 2122 are arranged alternately along the annular edge direction of the first color resist unit 211, so as to avoid the case where the multiple first hollows 2121 are in contact with each other and the hollows are too large, thereby ensuring that the third structure 2103 has relatively uniform light transmittance at the boundary between the first color resist unit 211 and the first black matrix.

It is to be noted that the two third structures 2103 shown in FIG. 7 are only two of all applicable structures, and the positions and shapes of the first hollows 2121 in the provided third structure 2103 are not specifically limited in the embodiment of the present application and need to be designed specifically according to the actual application.

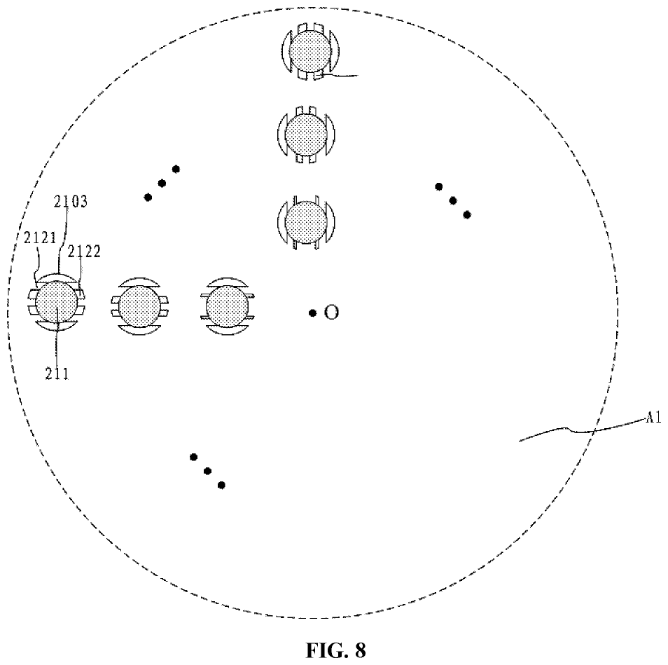

As shown in FIG. 8, FIG. 8 is a structural diagram illustrating the distribution of third structures according to an embodiment of the present application. In the third structure 2103, the opening area of the first hollows 2121 is negatively correlated to the distance from the third structure 2103 to the center O of the first display region A1. That is, in the first display region A1, in the direction from the edge of the first display region A1 to the center O of the first display region A1, in the third structure 2103 closer to the center O of the first display region A1, the opening area of the first hollows 2121 is larger; conversely, in the third structure 2103 farther away from the center O of the first display region A1, the opening area of the first hollows 2121 is smaller.

It is to be understood that, in the third structure 2103, the larger the opening area of the first hollow 2121 is, the greater the light transmittance of the third structure 2103 is; in the embodiment of the present application, the opening area of the first hollows 2121 is configured to be negatively correlated to the distance from the third structure 2103 to the center O of the first display region A1 so that the light transmittance increases gradually in the direction from the edge of the first display region A1 to the center O of the first display region A1, that is, the light-transmissive brightness increases gradually in the direction from the edge of the first display region A1 to the center O of the first display region A1, and the light-transmissive brightness shows a smooth transitional increase trend in the direction from the second display region A2 to the first display region A1, so as to improve the problem of an excessive brightness difference at the boundary between the second display region A2 and the first display region A1, thereby improving the display effect of the display panel.

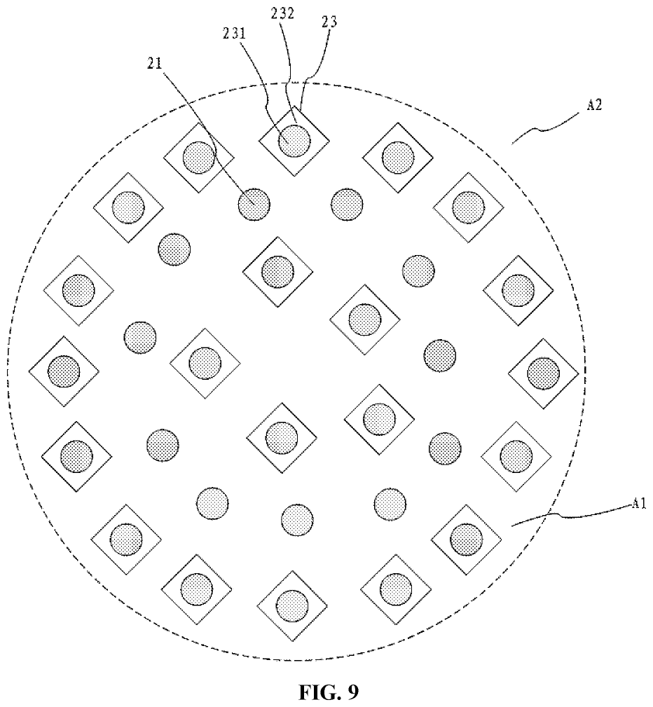

As shown in FIG. 9, FIG. 9 is a structural diagram of a first display region according to an embodiment of the present application. The display panel provided in the embodiment of the present application further includes a third optical filter structure 23, the third optical filter structure 23 is located in the first display region A1, the third optical filter structure 23 includes a third color resist unit 231 and a third black matrix 232 surrounding the third color resist unit 231, the filtered color of the third color resist unit 231 is the same as the filtered color of the second color resist unit 222 (or the first color resist unit 221), the thickness of the third color resist unit 231 is the same as the thickness of the second color resist unit 222, and in the direction from the second display region A2 to the first display region A1, the distribution density of the third filter structure 23 decreases gradually.

It is to be understood that the light transmittance of the third optical filter structure 23 provided in the embodiment of the present application is greater than or equal to the light transmittance of the second optical filter structure 22, and the light transmittance of the third optical filter structure 23 is less than the light transmittance of the first optical filter structure 21. The third optical filter structure 23 is disposed in the first display region A1, so as to avoid an excessive difference between the light transmittance of the first display region A1 and the light transmittance of the second display region A2, thereby ensuring a relatively small difference between the brightness of the first display region A1 and the brightness of the second display region A2 and improving the display effect of the display panel. Moreover, in the embodiment of the present application, the distribution density of the third optical filter structure 23 is configured to decrease gradually in the direction from the second display region A2 to the first display region A1 so that the brightness of the display panel can transition smoothly from the second display region A2 to the first display region A1, so as to avoid a bright line appearing at the boundary between the first display region A1 and the second display region A2, thereby further improving the display effect of the display panel.

Moreover, based on the solution in which the distribution density of the third optical filter structure decreases gradually in the direction from the second display region to the first display region, in the embodiment of the present application, the distribution density of the first optical filer structure may increase gradually in the direction from the second display region to the first display region so that the density of the first optical filter structure with high light transmittance and the density of the third optical filter structure with low light transmittance are complementary, thereby ensuring highly consistent brightness of the first display region and the second display region and improving the display effect of the display panel.

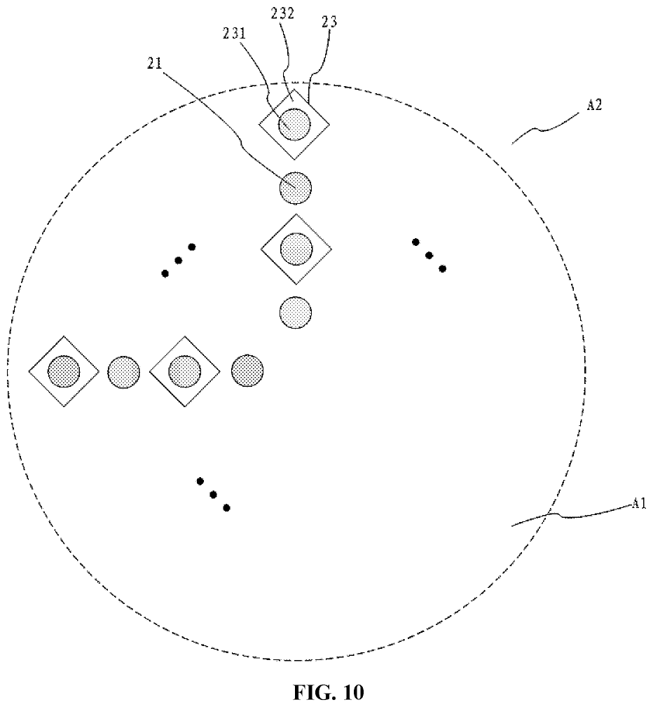

As shown in FIG. 10, FIG. 10 is a structural diagram of another first display region according to an embodiment of the present application. In the direction from the second display region A2 to the first display region A1, first optical filter structures 21 and third optical filter structures 23 are arranged alternately. Since the light transmittance of the first optical filter structure 21 and the light transmittance of the third optical filter structure 23 are different, when the first optical filter structures 21 are concentrated and the third filter optical structures 23 are concentrated, the difference in light transmittance between the concentrated region of the first optical filter structures 21 and the concentrated region of the third optical filter structures 23 is apparent; in the embodiment of the present application, the first optical filter structures 21 and the third optical filter structures 23 are arranged alternately, thereby avoiding a relatively large difference in light transmittance in different regions of the first display region A1, avoiding the brightness difference between different regions of the first display region A1, and improving the display effect of the display panel; on the other hand, the first optical filter structures 21 and the third optical filter structures 23 are arranged alternately, thereby reducing the influence of the first optical filter structure 21 on the color cast of the display panel.

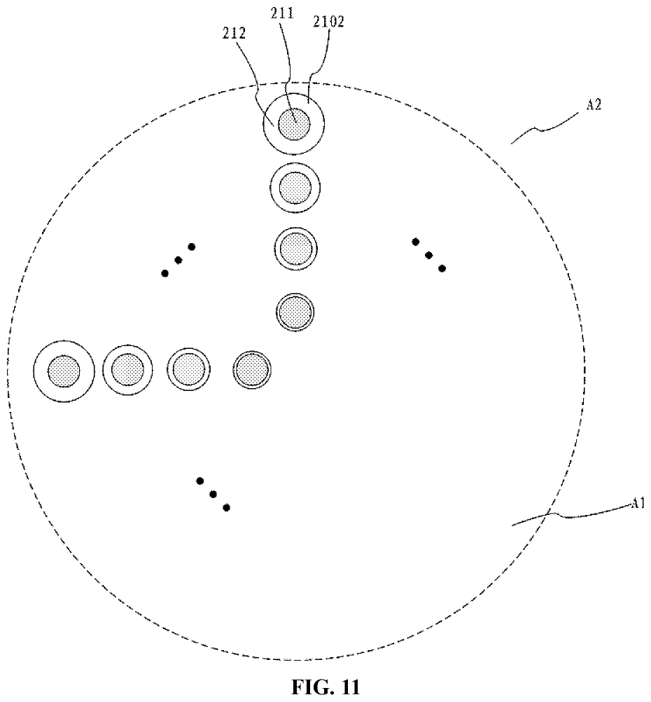

As shown in FIG. 11, FIG. 11 is a structural diagram illustrating the distribution of second structures according to an embodiment of the present application. The first optical filter structure includes the second structure 2102, and in the direction from the second display region A2 to the first display region A1, the width of the first black matrix 212 of the second structure 2102 decreases gradually. It is to be understood that among two second structures 2102 in the direction from the second display region A2 to the first display region A1, the width of the first black matrix 212 of the second structure 2102 closer to the second display region A2 is greater than the width of the first black matrix 212 of the second structure 2102 farther away from the second display region A2; that is, among the two second structures 2102 in the direction from the second display region A2 to the first display region A1, the light transmittance of the second structure 2102 closer to the second display region A2 is less than the light transmittance of the second structure 2102 farther away from the second display region A2 so that the light transmittance of the first display region A1 increases gradually in the direction from the second display region A2 to the first display region A1, and the brightness of the display panel can transition smoothly from the second display region A2 to the first display region A1, so as to avoid a bright line appearing at the boundary between the first display region A1 and the second display region A2, thereby further improving the display effect of the display panel.

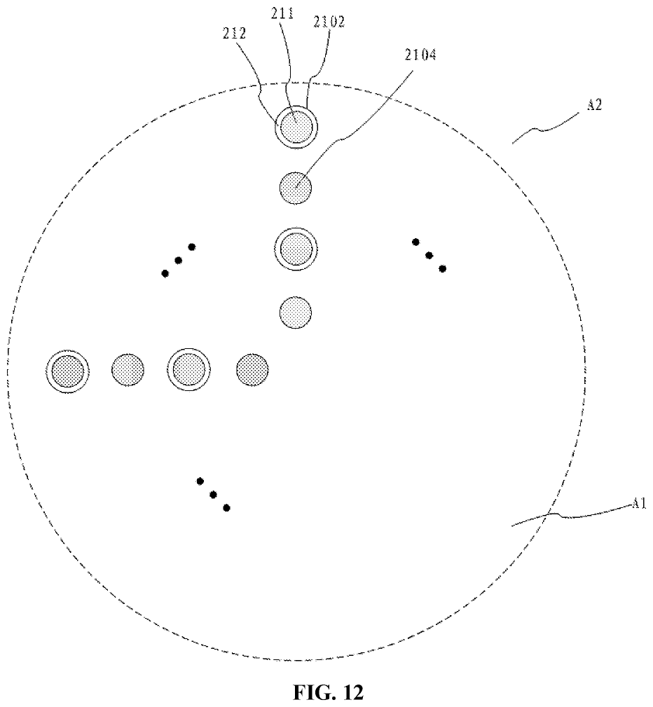

In an embodiment of the present application, the first optical filter structures provided in the present application include at least two of the first structure, the second structure, the third structure, or the fourth structure. As shown in FIG. 12, FIG. 12 is a structural diagram of another first display region according to an embodiment of the present application. The first display region A1 includes the second structure 2102 and the fourth structure 2104. To improve the display effect, in the first display region A1, two adjacent first optical filter structures are different. As shown in FIG. 12, one of the two adjacent first optical filter structures is the second structure 2102, and the other one of the two adjacent first optical filter structures is the fourth structure 2104.

It is to be understood that the first structure, the second structure, the third structure, and the fourth structure provided in the embodiment of the present application may have different light transmittance, and two adjacent first optical filter structures are configured to be different structures, so as to avoid the case where the concentrated arrangement of the first optical filter structures of the same type results in a relatively large difference between the light transmittance in the concentrated region and the light transmittance in other regions in the first display region, that is, a relatively large difference in light transmittance in different regions in the first display region is avoided, the color cast in different regions in the first display region is further avoided, and the display effect of the display panel is improved.

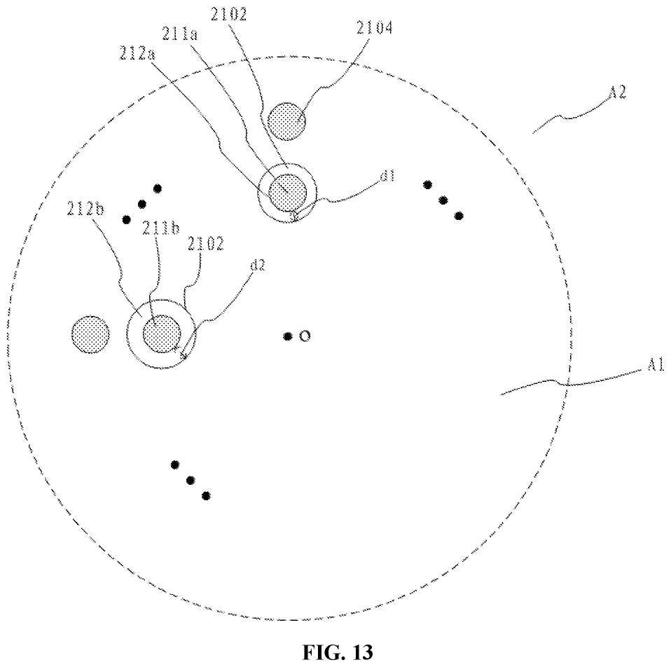

As shown in FIG. 13, FIG. 13 is a structural diagram of another first display region according to an embodiment of the present application. The first optical filter structure provided in the embodiment of the present application includes the second structure 2102; different first color resist units 211 include a first-color color resist unit 211a and a second-color color resist unit 211b which have different filtered colors, the difference between the distance from the first-color color resist unit 211a to the center O of the first display region A1 and the distance from the second-color color resist unit 211b to the center O of the first display region A1 is a preset value, the width of a first black matrix 212a surrounding the first-color color resist unit 211a is d1, the width of a first black matrix 212b surrounding the second-color color resist unit 211b is d2, and d1<d2.

It is to be noted that at least a transparent region exists between the first optical filter structures in the first display region, and the width of the first black matrix may be understood as the dimension of the first black matrix in the direction from the first black matrix to the first color resist unit and parallel to a plane where the display panel is located in the first optical filter structure.

It is to be understood that, in the embodiment of the present application, the filtered color of the first-color color resist unit 211a and the filtered color of the second-color color resist unit 211b are different; in the same optical filter structure, the viewing-angle brightness attenuation speed of the first-color color resist unit 211a emitting light is greater than the viewing-angle brightness attenuation speed of the second-color color resist unit 211b emitting light; in the embodiment of the present application, within approximately equal or equal distances from the center O of the first display region A1, the width d1 of the first black matrix 212a corresponding to the first-color color resist unit 211a is configured to be less than the width d2 of the first black matrix 212b corresponding to the second-color color resist unit 211b, thereby balancing the inconsistent viewing-angle brightness attenuation speed of the first-color color resist unit 211a emitting light and the second-color color resist unit 211b emitting light and ensuring a high display effect of the display panel.

In an embodiment of the present application, the preset value provided in the present application may be less than or equal to 20 microns. Moreover, the first-color color resist unit 211a provided in the embodiment of the present application is a green color resist unit, and the green color resist unit emits green light and filters out light of other colors; moreover, the second-color color resist unit 211b may be a red color resist unit or a blue color resist unit, the red color resist unit emits red light, and the blue color resist unit emits blue light.

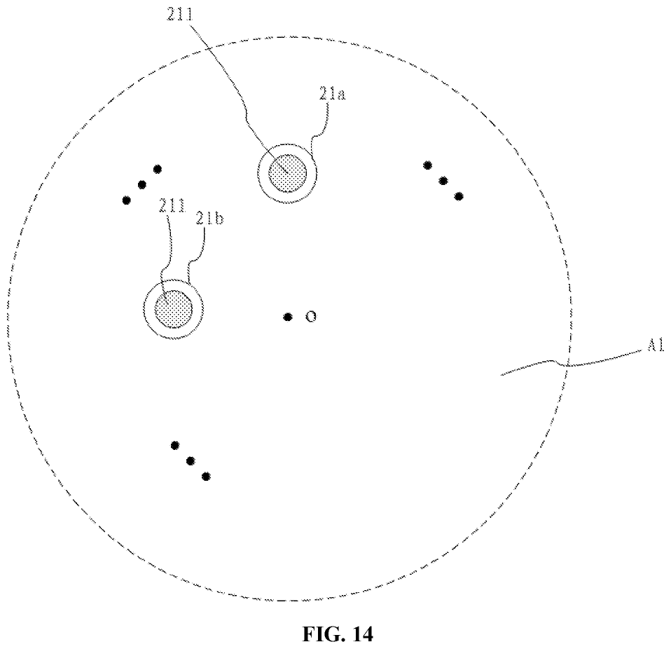

As shown in FIG. 14, FIG. 14 is a structural diagram of another first display region according to an embodiment of the present application. The first optical filter structures provided in the present application include a first-color optical filter structure 21a with a filtered color of a first color and a second-color optical filter structure 21b with a filtered color of a second color; the viewing-angle brightness attenuation speed of an optical filter structure corresponding to the first color is greater than the viewing-angle brightness attenuation speed of the same optical filter structure corresponding to the second color, where the light transmittance of the first-color optical filter structure 21a is greater than the light transmittance of the second-color optical filter structure 21b. The difference between the distance from the first color resist unit 211 of the first-color optical filter structure 21a to the center O of the first display region A1 and the distance from the first color resist unit 211 of the second-color optical filter structure 21b to the center O of the first display region A1 is a preset value.

It is to be understood that in the embodiment of the present application, the viewing-angle brightness attenuation speed of an optical filter structure corresponding to the first color is greater than the viewing-angle brightness attenuation speed of the same optical filter structure corresponding to the second color. Therefore, in a region with approximately equal or equal distances from the center O of the first display region A1, the light transmittance of the first-color optical filter structure 21a is improved, thereby balancing the inconsistent viewing-angle brightness attenuation speed of the first-color optical filter structure 21a and the second-color optical filter structure 21b and ensuring a high display effect of the display panel. In the embodiment of the present application, the first color is green, and the second color is red or blue.

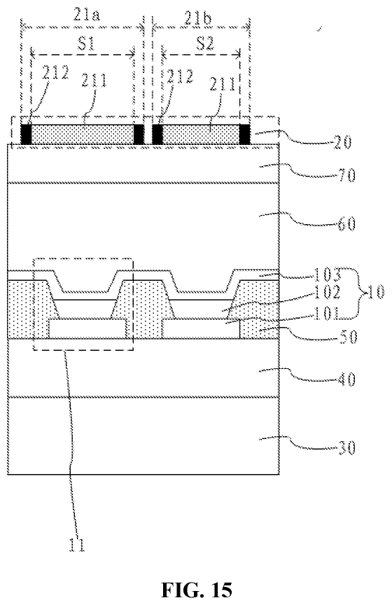

In the embodiment of the present application, the light transmittance of the first-color optical filter structure and the light transmittance of the second-color optical filter structure can be adjusted by adjusting the opening area of the black matrix in the optical filter structure. As shown in FIG. 15, FIG. 15 is a structural diagram of another display panel according to an embodiment of the present application. The first optical filter structure includes the first black matrix 212, the first black matrix 212 includes a light-transmissive hollow, and the first color resist unit 211 fills the light-transmissive hollow; the opening area S1 of the light-transmissive hollow of the first-color optical filter structure 21a is greater than the opening area S2 of the light-transmissive hollow of the second-color optical filter structure 21b. Furthermore, the opening area S1 of the light-transmissive hollow of the first-color optical filter structure 21a is increased so that the light transmittance of the first-color optical filter structure 21a is adjusted to be greater than the light transmittance of the second-color optical filter structure 21b, the inconsistent viewing-angle brightness attenuation speed of the first-color optical filter structure 21a and the second-color optical filter structure 21b is balanced, and a high display effect of the display panel is ensured.

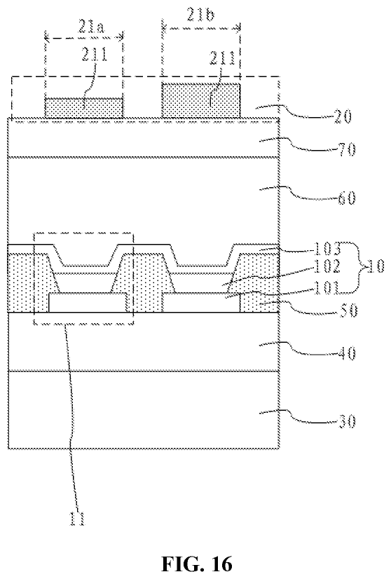

Alternatively, in the embodiment of the present application, the thickness of the first color resist unit may be adjusted, so as to adjust the light transmittance of the first-color optical filter structure and the light transmittance of the second-color optical filter structure. As shown in FIG. 16, FIG. 16 is a structural diagram of another display panel according to an embodiment of the present application. In the direction from the light-emitting unit 11 to the optical filter structure, the thickness of the first color resist unit 211 of the first-color optical filter structure 21a is less than the thickness of the first color resist unit 211 of the second-color optical filter structure 21b.

Furthermore, the thickness of the first color resist unit 211 of the first-color optical filter structure 21a is reduced so that the light transmittance of the first-color optical filter structure 21a is adjusted to be greater than the light transmittance of the second-color optical filter structure 21b, the inconsistent viewing-angle brightness attenuation speed of the first-color optical filter structure 21a and the second-color optical filter structure 21b is balanced, and a high display effect of the display panel is ensured.

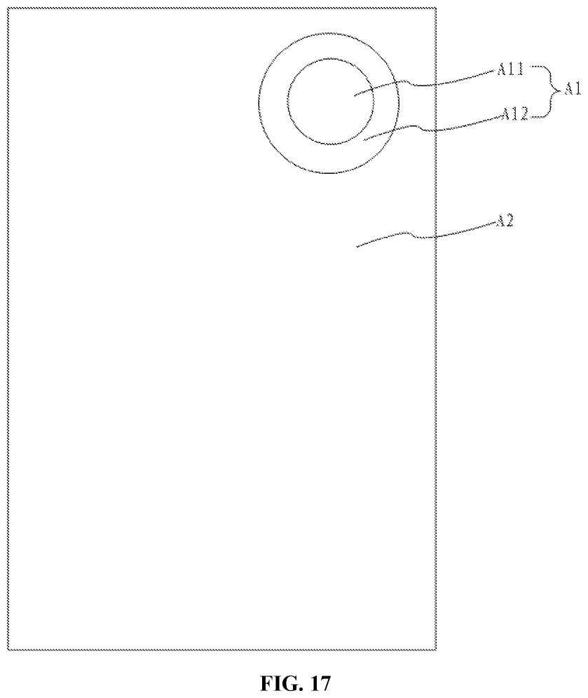

As shown in FIG. 17, FIG. 17 is a structural diagram of another display panel according to an embodiment of the present application. The first display region A1 includes a light-transmissive display region A11 and a transitional display region A12, where the transitional display region A12 is located between the light-transmissive display region A11 and the second display region A2; the light transmittance of the transitional display region A12 is less than the light transmittance of the light-transmissive display region A11.

It is to be understood that, in the embodiment of the present application, the transitional display region A12 is provided between the light-transmissive display region A11 and the second display region A2 so that the light transmittance can increase and transition smoothly from the second display region A2 to the light-transmissive display region A11, so as to ensure that the brightness difference of the display panel is relatively small at the boundaries between the second display region A2, the transitional display region A12, and the light-transmissive display region A11, thereby improving the display effect.

In an embodiment of the present application, when the first optical filter structure of the first display region provided in the present application includes the first structure, the thickness of the first color resist unit of the first structure in the light-transmissive display region is less than the thickness of the first color resist unit of the first structure in the transitional display region so that the light transmittance of the transitional display region is less than the light transmittance of the light-transmissive display region.

When the first optical filter structure includes the second structure, the width of the first black matrix of the second structure in the light-transmissive display region is less than the width of the first black matrix of the second structure in the transitional display region so that the light transmittance of the transitional display region is less than the light transmittance of the light-transmissive display region.

When the first optical filter structure includes the third structure, the opening area of the first hollows of the third structure in the light-transmissive display region is greater than the opening area of the first hollows of the third structure in the transitional display region so that the light transmittance of the transitional display region is less than the light transmittance of the light-transmissive display region.

Moreover, when the first optical filter structure includes the fourth structure, the thickness of the first color resist unit of the fourth structure in the light-transmissive display region is less than the thickness of the first color resist unit of the fourth structure in the transitional display region so that the light transmittance of the transitional display region is less than the light transmittance of the light-transmissive display region.

Correspondingly, the embodiment of the present application further provides a display device including the preceding display panel.

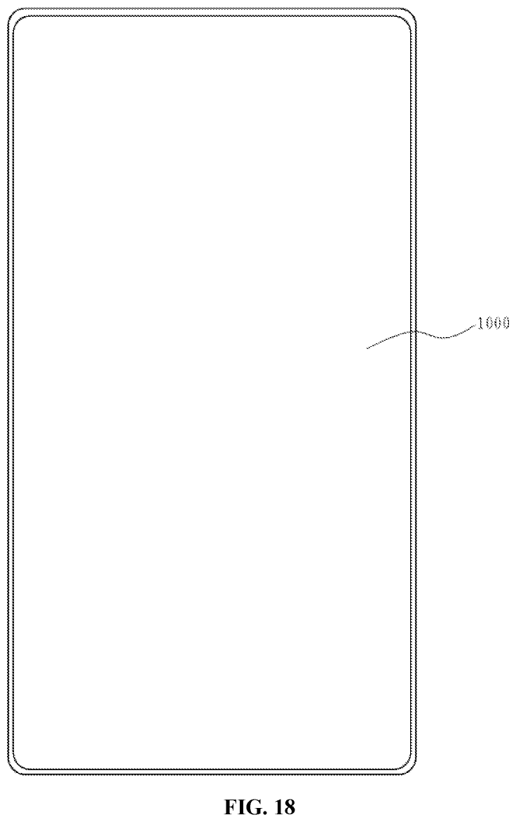

Referring to FIG. 18, FIG. 18 is a structural diagram of a display device according to an embodiment of the present application. A display device 1000 provided in the embodiment of the present application may be a mobile terminal device.

Optionally, the display device provided in the present application may also be an electronic display device such as a computer or a wearable display device, which is not specifically limited in the present application.

In an embodiment of the present application, the display device provided in the present application includes the photosensitive element, and the photosensitive element overlaps the first display region correspondingly. Specifically, the photosensitive element overlaps the light-transmissive display region of the first display region correspondingly. For example, the photosensitive element is a camera that may be disposed on the rear side of the display panel and overlap the light-transmissive display region of the display panel. Alternatively, photosensitive elements of other types may be disposed in the light-transmissive display region provided in the embodiment of the present application, which needs to be specifically designed according to the type of the display device. The photosensitive element provided in the embodiment of the present application overlaps the light-transmissive display region so that the photosensitive element can collect the light transmitted through the light-transmissive display region to work; moreover, the pixel circuit is not provided in the light-transmissive display region provided in the embodiment of the present application, thereby ensuring relatively high light transmittance in the light-transmissive display region and a better light collection effect of the photosensitive element.

The embodiments of the present application provide a display panel and a display device. The display panel includes a first display region and a second display region, where the second display region surrounds at least part of the first display region. The display panel includes a light-emitting layer and an optical filter layer, where the light-emitting layer includes multiple light-emitting units, the optical filter layer includes multiple optical filter structures, and the multiple light-emitting units are arranged corresponding to the multiple optical filter structures. The multiple optical filter structures include a first optical filter structure located in the first display region and a second optical filter structure located in the second display region, where the first optical filter structure includes a first color resist unit, and the second optical filter structure includes a second color resist unit. The filtered color of the first color resist unit and the filtered color of the second color resist unit are the same. The light transmittance of the first optical filter structure is greater than the light transmittance of the second optical filter structure.

It can be seen that in the embodiments of the present application, the light transmittance of the first optical filter structure is configured to be greater than the light transmittance of the second optical filter structure, further improving the light transmittance in the first display region, thereby improving the light collection effect in the region corresponding to the first display region.

In the description of the present application, it is to be understood that the orientations or position relations indicated by terms “center”, “longitudinal”, “lateral”, “length”, “width”, “thickness”, “above”, “below”, “front”, “rear”,” “left”, “right”, “vertical”, “horizontal”, “top” “bottom”, “inside”, “outside”, “clockwise”, “counterclockwise”, “axial direction”, “radial direction”, “circumferential direction”, and the like are based on the orientations or position relations shown in the drawings, merely for facilitating the description of the present application and simplifying the description, and do not indicate or imply that the apparatus or element referred to has a specific orientation and is constructed and operated in a specific orientation, and thus it is not to be construed as limiting the present application.

Moreover, terms such as “first” and “second” are merely for the description and are not to be construed as indicating or implying relative importance or implicitly indicating the number of technical features as indicated. Thus, a feature defined as a “first” feature or a “second” feature may expressly or implicitly include at least one “first” feature or at least one “second” feature. In the description of the present application, “plurality” is defined as at least two, for example, two or three, unless otherwise expressly and specifically limited.

In the present application, unless otherwise expressly specified and limited, the terms “assembly”, “connected to each other”, “connected”, “fixed”, and the like are to be construed in a broad sense, for example, as fixedly connected, detachably connected, or integrated; mechanically connected, electrically connected, or communicating with each other; directly connected to each other or indirectly connected to each other via an intermediary; or internally connected or an interactional relationship between two elements unless otherwise expressly limited. For those of ordinary skill in the art, specific meanings of the preceding terms in the present application may be understood according to specific situations.

In the present application, unless otherwise expressly specified and limited, when a first feature is described as “above” or “below” a second feature, the first feature is in direct contact with the second feature or the first feature is in indirect contact with the second feature via an intermediary. Moreover, when the first feature is described as “on”, “above”, or “over” the second feature, the first feature is right on, above, or over the second feature or the first feature is obliquely on, above, or over the second feature, or the first feature is simply at a higher level than the second feature. When the first feature is described as “under”, “below”, or “underneath” the second feature, the first feature is right under, below, or underneath the second feature or the first feature is obliquely under, below, or underneath the second feature, or the first feature is simply at a lower level than the second feature.

In the present application, the term such as “an embodiment”, “some embodiments”, “example”, “specific example”, “some examples”, or the like means that the specific characteristic, structure, material, or feature described in conjunction with the embodiment or example is included in at least one embodiment or example of the present application. In the specification, the illustrative description of the preceding terms does not necessarily refer to the same embodiment or example. Moreover, the described specific characteristic, structure, material, or feature may be combined properly in one or more embodiments or examples. In addition, those skilled in the art can combine different embodiments or examples and features of different embodiments or examples described in the specification without conflicting with each other.

Although the embodiments of the present application are illustrated and described above, it is to be understood that the preceding embodiments are exemplary and should not be construed as limiting the present application, and those of ordinary skill in the art can perform changes, modifications, substitutions, and variations on the preceding embodiments within the scope of the present application.

1. A display panel, comprising a first display region land a second display region, wherein the second display region surrounds at least part of the first display region;
the display panel comprises a light-emitting layer and an optical filter layer, wherein the light-emitting layer comprises a plurality of light-emitting units, the optical filter layer comprises a plurality of optical filter structures, and the plurality of light-emitting units are arranged corresponding to the plurality of optical filter structures;
the plurality of optical filter structures comprise a first optical filter structure located in the first display region and a second optical filter structure located in the second display region, wherein the first optical filter structure comprises a first color resist unit, and the second optical filter structure comprises a second color resist unit;
a filtered color of the first color resist unit and a filtered color of the second color resist unit are the same; and
light transmittance of the first optical filter structure is greater than light transmittance of the second optical filter structure.

2. The display panel of claim 1, wherein
the second optical filter structure further comprises a second black matrix surrounding the second color resist unit; and
the first optical filter structure comprises at least one of the following structures:
a first structure comprising the first color resist unit and a first black matrix surrounding the first color resist unit, wherein a thickness of the first color resist unit is less than a thickness of the second color resist unit;
a second structure comprising the first color resist unit and a first black matrix surrounding the first color resist unit, wherein a width of the first black matrix is less than a width of the second black matrix;
a third structure comprising the first color resist unit and a first black matrix surrounding the first color resist unit, wherein the first black matrix comprises a first hollow and a black matrix block, and the first hollow penetrates the first black matrix and extends to the first color resist unit in a direction from the first black matrix to a center of the first color resist unit; or
a fourth structure comprising the first color resist unit, wherein the first black matrix is not disposed around the first color resist unit.

3. The display panel of claim 2, wherein
the first optical filter structure comprises the fourth structure, and in the fourth structure, the thickness of the first color resist unit is less than the thickness of the second color resist unit.

4. The display panel of claim 2, wherein
the first optical filter structure comprises the third structure and in the third structure, the first hollow and the black matrix block are arranged alternately.

5. The display panel of claim 4, wherein
in the third structure, an opening area of the first hollow is negatively correlated to a distance from the third structure to a center of the first display region.

6. The display panel of claim 1, further comprising:
a third optical filter structure located in the first display region and comprising a third color resist unit and a third black matrix surrounding the third color resist unit;
wherein a filtered color of the third color resist unit is the same as the filtered color of the second color resist unit, and a thickness of the third color resist unit is the same as a thickness of the second color resist unit; and
in a direction from the second display region to the first display region, a distribution density of the third optical filter structure decreases gradually.

7. The display panel of claim 6, wherein
in the direction from the second display region to the first display region, a distribution density of the first optical filter structure increases gradually.

8. The display panel of claim 6, wherein
in the direction from the second display region to the first display region, the first optical filter structure and the third optical filter structure are arranged alternately.

9. The display panel of claim 2, wherein
the first optical filter structure comprises the second structure, and in a direction from the second display region to the first display region, a width of the first black matrix of the second structure gradually decreases.

10. The display panel of claim 2, wherein
the first optical filter structure comprises at least two of the first structure, the second structure, the third structure, or the fourth structure.

11. The display panel of claim 10, wherein
two adjacent first optical filter structures are different.

12. The display panel of claim 10, wherein
the first optical filter structure comprises the second structure; and
different first color resist units comprise a first-color color resist unit and a second-color color resist unit which have different filtered colors, a difference between a distance from the first-color color resist unit to a center of the first display region and a distance from the second-color color resist unit to the center of the first display region is a preset value, a width of the first black matrix surrounding the first-color color resist unit is d1, a width of the first black matrix surrounding the second-color color resist unit is d2, and d1<d2.

13. The display panel of claim 12, wherein
the preset value is less than or equal to 20 microns.

14. The display panel of claim 12, wherein
the first-color color resist unit is a green color resist unit.

15. The display panel of claim 1, wherein
the first optical filter structures comprises a first-color optical filter structure with a filtered color of a first color and a second-color optical filter structure with a filtered color of a second color; and
a viewing-angle brightness attenuation speed of an optical filter structure corresponding to the first color is greater than a viewing-angle brightness attenuation speed of a same optical filter structure corresponding to the second color, wherein light transmittance of the first-color optical filter structure is greater than light transmittance of the second-color optical filter structure.

16. The display panel of claim 15, wherein
the first optical filter structure comprises a first black matrix, the first black matrix comprises a light-transmissive hollow, and the first color resist unit fills the light-transmissive hollow; and
an opening area of the light-transmissive hollow of the first-color optical filter structure is greater than an opening area of the light-transmissive hollow of the second-color optical filter structure.

17. The display panel of claim 15, wherein
a thickness of the first color resist unit of the first-color optical filter structure is less than a thickness of the first color resist unit of the second-color optical filter structure.

18. The display panel of claim 1, wherein
the first display region comprises a light-transmissive display region and a transitional display region, wherein the transitional display region is located between the light-transmissive display region and the second display region; and
light transmittance of the transitional display region is less than light transmittance of the light-transmissive display region.

19. A display device, comprising a display panel,
wherein the display panel comprises a first display region and a second display region, wherein the second display region surrounds at least part of the first display region;
the display panel comprises a light-emitting layer and an optical filter layer, wherein the light-emitting layer comprises a plurality of light-emitting units, the optical filter layer comprises a plurality of optical filter structures, and the plurality of light-emitting units are arranged corresponding to the plurality of optical filter structures;
the plurality of optical filter structures comprise a first optical filter structure located in the first display region and a second optical filter structure located in the second display region, wherein the first optical filter structure comprises a first color resist unit, and the second optical filter structure comprises a second color resist unit;
a filtered color of the first color resist unit and a filtered color of the second color resist unit are the same; and
light transmittance of the first optical filter structure is greater than light transmittance of the second optical filter structure.

20. The display device of claim 19, further comprising a photosensitive element.
